(19) United States
(12) Patent Application Publication
(10) Pub. No.: US 2006/0161711 A1
(43) Pub. Date: Jul. 20, 2006

(54) Information device

(75) Inventor: Hiroshi Inoue, Kanagawa (JP)

Correspondence Address: HOGAN & HARTSON L.L.P., 500 S. GRAND AVENUE, SUITE 1900, LOS ANGELES, CA, 90071-2611, US

(73) Assignee: KYOCERA CORPORATION

(21) Appl. No.: 11/317,325

(22) Filed: Dec. 22, 2005

(30) Foreign Application Priority Data
Dec. 24, 2004 (JP) P.2004-375027
Jan. 25, 2005 (JP) P.2005-017319

(51) Int. Cl. H05K 7/10

(52) U.S. Cl. 710/301

(57) ABSTRACT

An information device is provided, which can be prevented from being pulled out by mistake from an information processing terminal beforehand, but can be pulled out safely. The device is provided with an interface, a CPU, a modem portion, a memory portion, and sensors to a projection portion. A sounding buzzer portion and an LED display portion are provided to an upper portion of the projection portion. A notice (first notice) is given when a user pushes the pair of sensors in a state where the safe pull-out cannot be executed. A process of enabling the safe pull-out is executed after this notice, and when this process ends, a notice (second notice) is given by the sounding buzzer portion and the LED display portion.

This application claims foreign priorities based on Japanese Patent applications No. 2004-375027 filed Dec. 24, 2004, and No. 2005-017319 filed Jan. 25, 2005, the contents of which are incorporated herein by reference in their entirety.

### BACKGROUND OF THE INVENTION

1. Field of the Invention

The present invention relates to an information device such as an information storing device and a radio communication device, which is used by being installed detachably into an information processing terminal such as a notebook computer.

2. Description of the Related Art

When a work is carried out with an information processing terminal such as a notebook computer, data transfer is performed by using an information storing device, or information is exchanged by using a radio communication device having a radio communicating section to connect to an external communication network, for example. These devices are used by being inserted into an insertion slot such as a card slot which is provided in the information processing terminal, and these devices can be taken out of the insertion slot when they are not in use. In the related art, an information processing terminal is considered that can prevent a program from running out of control, a system from being reset, or the like, when these devices are taken out by mistake during execution of a program installed therein (refer to JP-A-5-28327 and JP-UM-A-6-4852).

Meanwhile, in the case of the information storing terminal, saving data or the like cannot be written into the memory unless the device is taken out after a predetermined process (device operation terminating process) is executed in the information processing terminal. Therefore, in some cases the device becomes unstable and thus the data stored in the memory is destroyed. Also, such a wrongful process makes the OS (operating system) of the information processing terminal unstable, which causes failure of the information processing terminal.

Moreover, in the case of the radio communication device, for example, when the radio communication device is pulled out while a rewriting of PRL (roaming area information) or a writing of ID (identification) information such as a phone number is being executed by using OTA (Over The Air), the information having been rewritten or the information having been written until at that time becomes unavailable. Therefore, when the rewriting or the writing of the information as described above is executed once again by inserting the radio communication device into the insertion slot of the information processing terminal, the rewriting or the like of the information must be done all over again, which yields a waste of time. In addition, in such a case, since the device also becomes unstable, sometimes a failure occurs such that the device does not operate normally, or the like. Further, such a problem arises that the communication condition gets worse, or the like, as a workload on a base station side is increased.

Moreover, in the case of the radio communication device, the radio communication device holds session information with the base station during communication. When the radio communication device is pulled out before the session information is held, the radio communication device needs to hold the session information again in the subsequent communication connection. Therefore, such a disadvantage is caused that it takes much time for the connection of the radio communication device.

### SUMMARY OF THE INVENTION

It is an object of the present invention to provide an information device such as an information storing device and a radio communication device, which can be prevented beforehand from being pulled out from an information processing terminal by mistake, but can be pulled out safely from the information processing terminal.

An information device of the present invention comprises: an interface connectable to an information processing terminal; a storage; a detector provided to be pushed or touched when the information device is pulled out from the information processing terminal, the detector detects a pushed state or a touched state of the detector; an informing section; and a controller which controls the informing section to give a first notice in a case where it is inappropriate to pull out the information device when the detector detects the pushed state or the touched state. In the information device of the present invention, the controller controls to issue a command to the information processing terminal so that the information processing terminal executes a process for enabling a safe pull-out of the information device after the first notice is given, and the controller controls the informing section to give a second notice when the information processing terminal executes the process for enabling the safe pull-out based on the command.

The first notice by the informing section is given for the purpose of warning the user so as not to pull out the information device by mistake from the information processing terminal. The second notice is given for the purpose of informing the user that the pull-out is allowed (permitted).

Also, the information device of the present invention comprises: an insertion portion positioned inside the information processing terminal in a state where the interface is connected to the information processing terminal; and a projection portion positioned outside the information processing terminal in the state where the interface is connected to the information processing terminal.

In this case, in order to give the notice for drawing the user's attention without fail, the informing section is provided in the projection portion, for example.

In the information device of the present invention, the case where it is inappropriate to pull out the information device signifies a case where electric power is supplied to the information device, i.e., a case where the power supply is in its ON state.

Also, in the information device of the present invention, the case where it is inappropriate to pull out the information device signifies a case where the information processing terminal does not execute a process of stopping an operation of the information device.

This signifies a state where a safe removal of the information device is not allowed in the information processing terminal, i.e., a state where a process of turning OFF the power supply is now executed after the information device receives a request for turning OFF the power-supply from the information processing terminal (a state where the writing of the saving data is being executed at the end of the process).

Also, in the information device of the present invention, the case where it is inappropriate to pull out the information device signifies a case where information is being written in the storage. The case may signify the writing of the data (memory) from the information processing terminal.

Normally the user holds (grasps) the outer peripheral portion (e.g., upper and lower portions or both side portions) of the projection portion with a thumb and an index finger, or the like, when the user tries to pull out the information device from the information processing terminal. Therefore, in the present invention, in order to execute the detection during the flow of such pulling-out operation, the detector has a sensor for detecting a press or a touch thereof, and is provided in the projection portion (e.g., in upper and lower portions or both side portions).

When the user tries to pull out the information device from the information processing terminal, in most cases the user pulls out the information device by holding the upper and lower portions or both side portions of the projection portion with the thumb and the index finger, or the like. Therefore, in the present invention, in order to execute the exact detection in response to such pulling-out operation, the detector has a sensor for detecting a press or a touch thereof, and a pair of the detectors are provided in an upper and lower portions or both side portions of the projection portion, and when the pair of detectors are pushed or touched, the informing section gives the first notice by the control of the controller.

Also, in the present invention, the detector has a pressure sensor, a pair of the detectors are provided in both side portions of the insertion portion, and the pair of detectors come into contact with an inner surface of the information processing terminal in a state where the insertion portion is inserted in the information processing terminal.

With such a configuration, when the information device is pulled out, a pressure at that time can be detected by the pressure sensor. Therefore, in this case, the detection can surely be performed in the flow of the pulling-out operation.

Further, normally an eject button for moving the information device outside is provided in the information processing terminal. Thus, the user moves the information device outside by pushing this eject button so as to pull out the information device. Therefore, in the present invention, in order to execute the detection corresponding to the flow of such pulling-out operation in the related art, the detector is provided in a position that opposes to a push-out member in the information processing terminal, the push-out member being provided so as to move in a pulling-out direction when an eject button provided to the information processing terminal is pushed.

Meanwhile, in the present invention, in order to inform the user without fail, the informing section includes an audio section and a display, for example. In this case, the audio section is configured with, for example, a piezoelectric buzzer to sound or a synthesized sound played from a speaker. The display is configured with, for example, an LED lamp or the like for flashing. In this case, in the present invention, in order to give the user the warning to prevent the pull-out more surely, it is preferable that both the audio section and the display are employed.

Also, in the present invention, the first notice is displayed on a display of the information processing terminal. In this case, in order to show the display on the screen of the information processing terminal to prevent the pull-out, a predetermined program, i.e., a program designed such that the display to prevent the pull-out can be given on the screen of the information processing terminal must be input into the information processing terminal. In this case, such a program can be input simply into the information processing terminal, just by including the program in a driver software (device driver) of the information device to be installed in the information processing terminal.

Also, the information device of the present invention comprises: a radio communicating section, wherein the information is obtained through the radio communicating section.

In the information device of the present invention, the controller controls to issue a command to the information processing terminal so that the information processing terminal executes a process for enabling a safe pull-out of the information device after the first notice is given, and the controller controls the informing section to give a second notice when the information processing terminal executes the process for enabling the safe pull-out based on the command.

In this case, there are examples of the case where information is being written in the storage, such as a rewriting of PRL (roaming area information), a rewriting of ID information such as a phone number, an update of a firmware or a function of the radio communicating section, all of which are by OTA (Over The Air). Also, cases where the radio communicating section is in an idle state and performs a handover (handoff) are included in the examples of the case where it is inappropriate to pull out the information device.

### BRIEF DESCRIPTION OF THE DRAWINGS

FIG. 1 is a schematic plan view showing a state that a PC card as a radio communication device according to the present invention is inserted into an insertion slot of an information processing terminal.

FIG. 2 is a block diagram showing a configuration of a PC card as a radio communication device according to the present invention.

FIG. 3 is a flowchart showing an operation of a PC card as a radio communication device according to the present invention.

FIG. 4 is a flowchart showing an operation of a PC card as an information storing device according to the present invention, having a flash memory.

FIG. 5 is a flowchart showing a process of pulling out an information storing device and a radio communication device according to the present invention.

FIG. 6 is a flowchart showing another process of pulling out an information storing device a radio communication device according to the present invention.

FIG. 7 is a block diagram showing a configuration of a PC card as another radio communication device according to the present invention.

FIG. 8 is a perspective view showing a PC card as other radio communication device according to the present invention.

FIG. 9 is a schematic plan view showing a situation that a PC card as still another radio communication device according to the present invention is inserted into an insertion slot of the information processing terminal.

FIG. 10 is a schematic plan view showing a situation that a PC card as yet still another radio communication device according to the present invention is inserted into an insertion slot of the information processing terminal.

### DESCRIPTION OF THE PRFERRED EMBODIMENTS

A best mode for carrying out the present invention will be explained in detail with reference to the drawings hereinafter. In this case, the information device such as the information storing device and the radio communication device according to the present invention will be explained with a PC card as an example.

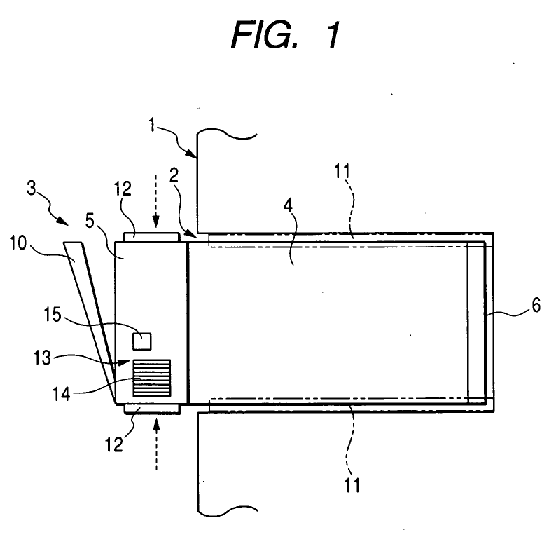

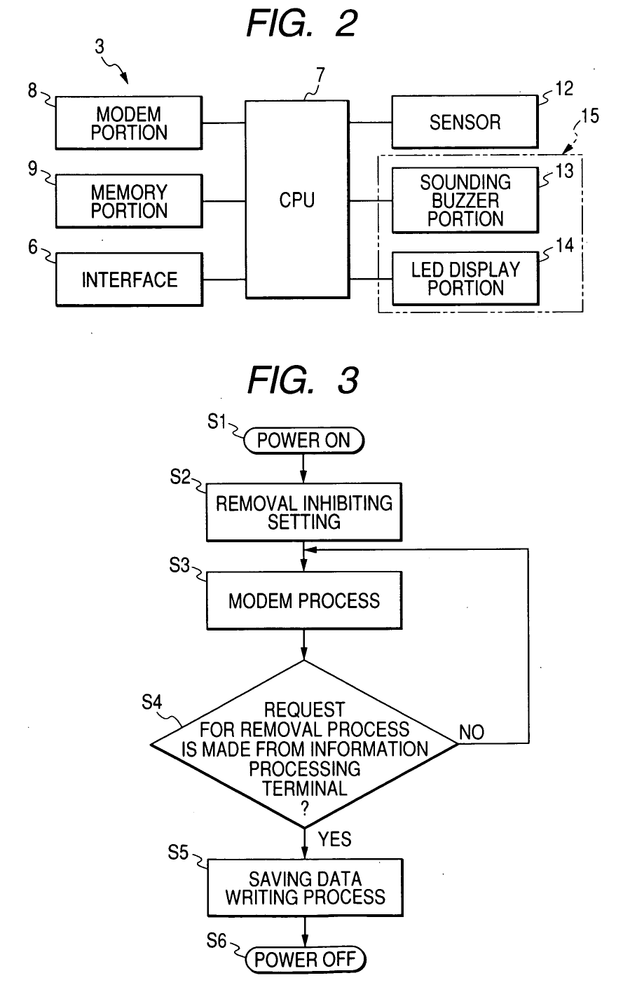

FIG. 1 is a schematic plan view showing a state that a PC card as a radio communication device according to the present invention is inserted into an insertion slot (a card slot, in the present embodiment) of an information processing terminal. FIG. 2 is a block diagram showing a configuration of the PC card as the radio communication device according to the present invention.

Normally, a widespread information processing terminal 1 such as a notebook computer is provided with a card slot (insertion slot) 2 into which a PC card or the like is inserted. A PC card 3 of the present invention can be inserted into this card slot 2. The PC card 3 is configured with an insertion portion 4 which positions inside the card slot 2, and a projection portion 5 which positions outside the card slot 2, when the PC card 3 is inserted into the card slot 2. The PC card 3 further comprises: an interface 6 to be connected to a connector portion (not shown) inside the card slot 2 of the information processing terminal 1; a CPU (controller) 7 for controlling an overall device, and giving a process command so that the PC card 3 can be pulled out (removed) safely from the information processing terminal 1; a modem portion 8; and a memory portion (storage) 9. A numeral 10 is a foldable antenna for radio communication provided to the projection portion 5.

The insertion portion 4 is formed so as to be inserted between a pair of card guide rails 11 provided to both side portions in the card slot 2 of the information processing terminal 1. A pair of sensors (detector) 12 are provided to both side portions of the projection portion 5 so as to project outwardly. The pair of sensors 12 is provided so that the sensors 12 can be slightly pushed in toward the center side of the projection portion 5 in its width direction, and are configured so as to be able to detect the pushed state. In this case, the sensors 12 may be configured so as to be able to detect a state in which the sensors 12 are being touched.

A sounding buzzer portion (audio section) 13 and an LED (light-emitting diode) display portion (display) 14 are provided on an upper surface portion of the projection portion 5 for informing a user of the pull out of the PC card 3. The sounding buzzer portion 13 and the LED display portion 14 constitute an informing section 15.

In a situation that the PC card 3 cannot be pulled out safely, the informing section 15 is controlled so as to operate as follows: when the user pushes the pair of sensors 12, the sounding buzzer portion 13 makes a sound and the LED display portion 14 flashes on and off (first notice); and when the user looses hold of the pair of sensors 12, or after a predetermined time has elapsed, the sounding buzzer portion 13 stops the sound and the LED display portion 14 is brought into its OFF state. Also, in a situation that the PC card 3 can be pulled out safely under the control of the CPU 7 the informing section 15 is controlled so as to operate as follows: the sounding buzzer portion 13 makes the sound and the LED display portion 14 flashes on and off (second notice); and after a predetermined time has elapsed, the sounding buzzer portion 13 stops the sound and the LED display portion 14 is brought into its OFF state.

In the present invention, particularly the sounding buzzer portion 13 is provided because the sound of the sounding buzzer portion 13 can draw the user's attention without fail even when the user fails to notice the flashing of the LED display portion 14.

FIG. 3 is a flowchart showing an operation of the PC card as the radio communication device according to the present invention. In this case, (S1) to (S6) in the flowchart show respective process steps of the operation.

When the PC card 3 is inserted into the card slot 2 under the condition that the information processing terminal 1 is in its ON state, or when the information processing terminal 1 is changed from the OFF state to the ON state under the condition that the PC card 3 is being inserted in the card slot 2 of the information processing terminal 1, the PC card 3 is also turned ON (Power On: S1). At this time, the CPU 7 of the PC card 3 makes a setting that inhibits the pull-out by mistake, more particularly a setting that causes the sounding buzzer portion 13 to sound and also the LED display portion 14 to flash when the pair of sensors 12 are pushed in (removal inhibiting setting: S2). The removal inhibiting setting (S2) is continued until a power supply of the PC card 3 is turned OFF.

After the removal inhibiting setting (S2) is done, for example when a communication process is being carried out by the modem portion 8 (modem process: S3), the CPU 7 determines whether or not a request for the pull-out process (removal process request) is made from the information processing terminal 1, that is, whether or not a process for stopping the operation of the PC card 3 is being executed in the information processing terminal 1 (S4).

Then, when the user starts the process for stopping the device operation of the PC card 3 by the information processing terminal 1, saving data is written in the memory portion 9 (saving data writing process: S5) Then, the power supply of the PC card 3 is turned OFF (Power Off: S6). As a result, the PC card 3 can be pulled out safely at this time. Incidentally, when the user does not start the process for stopping the device operation of the PC card 3 by the information processing terminal 1, the communication process is carried out by the modem portion 8 (S3).

The operation shown in FIG. 3 can also be executed in an information storing device. For example, when the information storing device is configured with a flash memory, an influence of the pull-out by mistake appears only when data are written into the flash memory (memory portion) (during data transfer). Therefore, in the case of the information storing device having the flash memory, the setting to inhibit the pull-out by mistake (removal) should be made for only when the data are written into the flash memory.

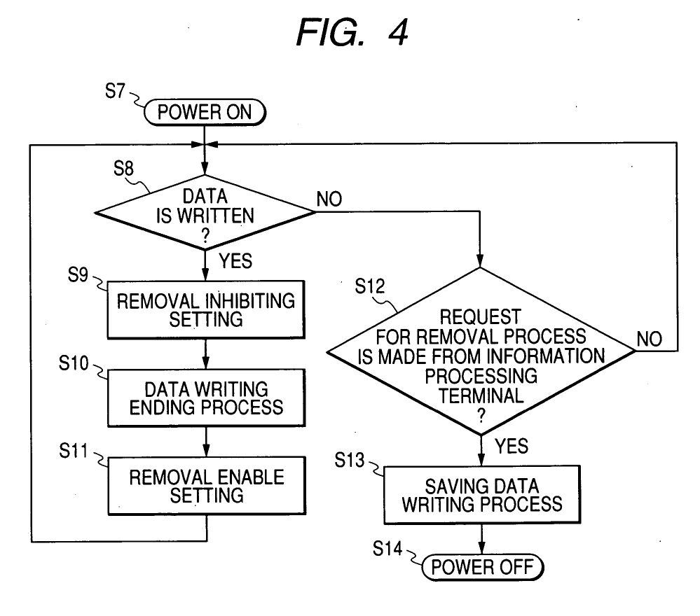

Next, an operation of the information storing device according to the present invention, having such flash memory, will be explained with reference to a flowchart shown in FIG. 4 hereunder. In this case, (S7) to (S14) in the flowchart show respective process steps of the operation. A PC card 16 (not shown) as the information storing device according to the present invention comprises: the insertion portion 4 and the projection portion 5 similarly to the PC card 3; the interface 6; the pair of sensors (detector) 12; the informing section 15; a CPU (controller) 17 for controlling an overall device, and giving a process command so that the PC card 16, can be pulled out safely from the information processing terminal 1; and a memory portion (storage) 18 configured with the flash memory.

When the PC card 16 is inserted into the card slot 2 under the condition that the information processing terminal 1 is in its ON state, or when the information processing terminal 1 is changed from its OFF state to the ON state under the condition that the PC card 16 is being inserted in the card slot 2 of the information processing terminal 1, the PC card 16 is also turned ON, like step S1 (Power On: S7). Then, the CPU 17 determines whether or not the data is being written from the information processing terminal 1 into the memory portion 18 (whether or not the data transfer is performed) (S8). If the data is being written into, a removal inhibiting setting is made, like step S2 (removal inhibiting setting: S9).

Then, after such removal inhibiting setting (S9) is made, this setting is continued until the writing of the data from the information processing terminal 1 is ended. Then, when the writing of the data is ended (data writing ending process: S10), the CPU 17 releases the removal inhibiting setting and also makes a setting to allow the pull-out (removal enable setting: S11). Therefore, after the removal enable setting (S11) is made, the PC card 16 can be pulled out safely.

Then, if the writing of the data is not being executed, the CPU 17 determines whether or not the request for the pull-out process (removal process request) is made from the information processing terminal 1, that is, that is, whether or not a process for stopping the operation of the PC card 16 is being executed in the information processing terminal 1 (S12). Then, when the user starts the process for stopping the device operation of the PC card 16 by the information processing terminal 1, saving data is written in the memory portion 18 (saving data writing process: S13). Then, the power supply of the PC card 16 is turned OFF (Power Off: S14). As a result, the PC card 16 can also be pulled out safely at this time.

By the way, the above operation is carried out in the information storing device having the flash memory. However, in the present invention, the above operation is not limited to such information storing device. The above operation may be executed in the radio communication device having a radio communicating section, in which the flash memory is provided. Then, the radio communication device in this case is configured so as to make the removal inhibiting setting (S9), when the operation that requires the writing of the information into the flash memory by using the radio communicating section is being executed (when the operation equivalent to the operation in S8 is executed). More particularly, for example, the cases by OTA (Over The Air) are [1] when the rewriting of PRL (roaming area information) is executed, [2] when the writing of ID information such as a phone number is executed, [3] when an update of a firmware or a function of the modem portion is executed, etc. Moreover, for example, the case is at the time of a handover (handoff) or during the idle operation.

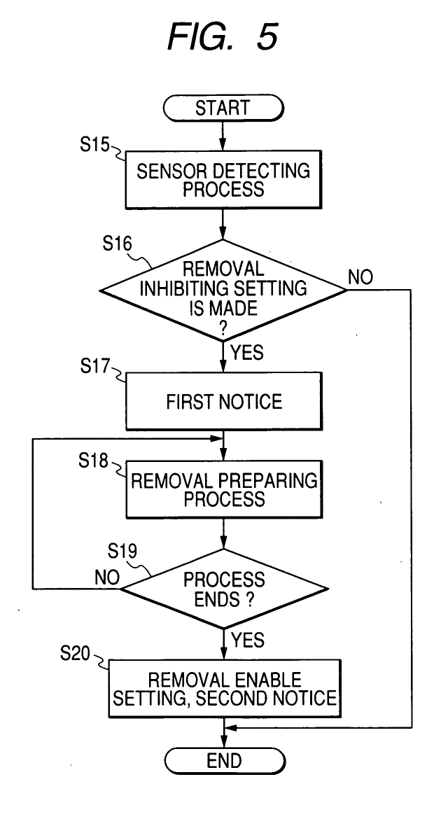

FIG. 5 is a flowchart showing a process of pulling out the information storing device and the radio communication device according to the present invention. In this case, (S15) to (S20) in the flowchart show respective process steps of the operation.

In a situation that the user intends to pull out the PC card 3, 16 from the information processing terminal 1 by pushing the pair of sensors 12 (or touching the pair of sensors 12) (sensor detecting process: S15), when the removal inhibiting setting (S16: which signifies S2, S9, and the same is true in the following.) is made in the PC card 3, 16, the sounding buzzer portion 13 makes a sound and the LED display portion 14 flashes on and off (first notice: S17). This first notice (S17) is performed for the purpose of drawing the user's attention to stop pulling out the PC card 3, 16 further. Therefore, the user can stop the pulling-out operation because the user can become aware of the pull-out by mistake, by recognizing the sound of the sounding buzzer portion 13 and the flashing of the LED display portion 14. In case the removal inhibiting setting (S16) is not made when the sensor detecting process (S15) is executed, the user can pull out the PC card 3, 16 safely.

As soon as the first notice (S17) is given, the process of enabling the safe pull-out (removal preparing process: S18) is started. In this removal preparing process (S18), a signal for giving a command of the process to enable the safe pull-out is output from the CPU 7, 17 of the PC card 3, 16 to a CPU (not shown) of the information processing terminal 1. Then, the information processing terminal 1 executes the process based on this signal. This process (S18) signifies the process of writing the saving data in the memory portion 9 (the process equivalent to S5) in the case of the PC card 3, and also signifies the process of ending the writing of the data into the memory portion 18 (the process equivalent to S10) in the case of the PC card 16.

When the writing of the data into the memory portion 9, 18 is ended (S19), the removal inhibiting setting (S16) is canceled and the setting that allows the pull-out is made (removal enable setting: S20). At this time, a signal for informing the end of process is output to the CPU 7, 17 of the PC card 3, 16 from the CPU of the information processing terminal 1. Also, the sounding buzzer portion 13 makes a sound once again and the LED display portion 14 flashes on and off, under control of the CPU 7, 17 based on this signal (second notice: S20). The second notice (S20) is performed for the purpose of informing the user that the PC card 3, 16 can be pulled out safely.

The user can recognize a timing to pull out the PC card 3, 16 by this second notice (S20). Accordingly, the user can pull out the PC card 3, 16 safely.

In order to execute a process in the information processing terminal 1 during the removal preparing process (S18) to the removal enable setting and the second notice (S20), a software in which a program for executing a predetermined process is recorded is installed in advance into the information processing terminal 1.

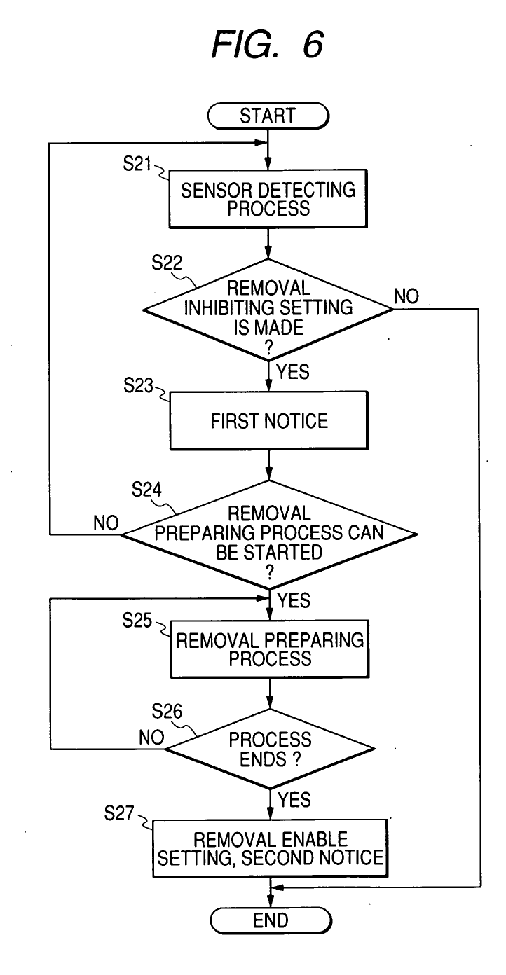

FIG. 6 is a flowchart showing another process of pulling out the information storing device and the radio communication device according to the present invention. In this case, (S21) to (S27) in the flowchart show respective process steps of the operation.

In this another process of pulling out the information storing device and the radio communication device according to the present invention, after the first notice (S23: same as S17), the user is informed of whether the removal preparing process (S25: same as S18) can be started, and also the information processing terminal 1 is enabled to accept or deny the starting of this removal preparing process (S24). In this case, steps S21 to S23 correspond to steps S15 to S17 respectively, and steps S25 to S27 correspond to steps S18 to S20 respectively.

In step S24, characters, etc. to inform the user of whether the removal preparing process (S25) can be started, and also a button used to accept (referred to as an “OK button” hereinafter) and a button used to deny (referred to as a “cancel button” hereinafter) the starting of the removal preparing process (S25) are displayed on a screen (not shown) of the information processing terminal 1 (not shown). Then, when the user operates the OK button or the cancel button (for example, the user moves a mouse pointer onto the OK button or the cancel button, and then clicks the mouse) based on this display, the CPU 7, 17 determines whether or not the removal preparing process (S25) is to be started. In step S24, when the OK button is operated, the removal preparing process (S25) is started, whereas when the cancel button is operated, the information processing terminal 1 goes to the idle state until the sensor detecting process (SS21) is executed once again.

By taking such steps, for example, the user can avoid the removal preparing process (S25) to continue the user's work when the user decides to stop the pull-out after pushing the sensors 12. Therefore, the user can use the PC card 3, 16 effectively in accordance with the user's intention.

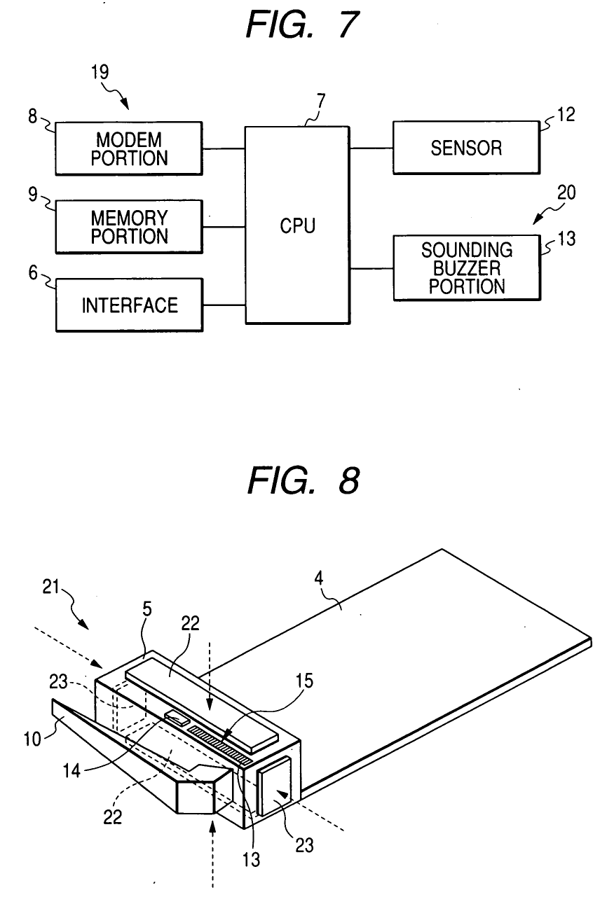

FIG. 7 is a block diagram showing a configuration of a PC card as another radio communication device according to the present invention.

Similarly to the PC card 3, a PC card 19 as another radio communication device is configured with the insertion portion 4 and the projection portion 5. Also, the PC card 19 comprises the interface 6, the CPU 7, the modem portion 8, the memory portion 9, the antenna portion 10, and the pair of sensors 12. Also, the projection portion 5 is provided with only the sounding buzzer portion (audio section) 13. Then, this PC card 19 is controlled such that, when the first notice (the notice equivalent to S17, S23) is performed, not only the sounding buzzer portion 13 can make a sound but also warning characters, etc. to prevent the pull-out can be displayed on the screen (not shown) of the information processing terminal 1. Also, the PC card 19 is controlled such that, when the second notice (the notice equivalent to S20, S27) is performed, not only the sounding buzzer portion 13 can make a sound but also characters, etc. to inform that the pull-out is enabled can be displayed on the screen (not shown) of the information processing terminal 1 (informing section 20). By using the PC card 19, the notice that appeals much more to the user's eyes can be offered to the user.

Here, in constituting the informing section 20, a software is installed into the information processing terminal 1, the software in which a program for displaying the warning characters, etc. on the screen in response to the detection of the pair of sensors 12 of the PC card 19 is input.

FIG. 8 is a perspective view showing a PC card as other radio communication device according to the present invention.

Similarly to the PC card 3, a PC card 21 as other radio communication device is configured with the insertion portion 4 and the projection portion 5. Also, the PC card 21 comprises the interface 6, the CPU 7, the modem portion 8, the memory portion 9, the antenna portion 10, and the informing section 15. Also, pairs (a set) of sensors 22, 23 are provided to upper and lower portions or both side portions of the projection portion 5 respectively. Then, this PC card 21 is configured in such a way that, when the pairs of sensors 22, 23 provided to the upper and lower portions or the both side portions of the projection portion 5 are pushed in a condition that the power supply is in the ON state, the sounding buzzer portion 13 makes a sound and also the LED display portion 14 flashes on and off. When the PC card 21 configured in this manner is employed, the user inevitably touches the pairs of sensors 22, 23 provided to the upper and lower portions or the both side portions of the projection portion 5 when the user tries to pull out the PC card 21. Therefore, the detection by the pairs of sensors 22, 23 can be done more surely.

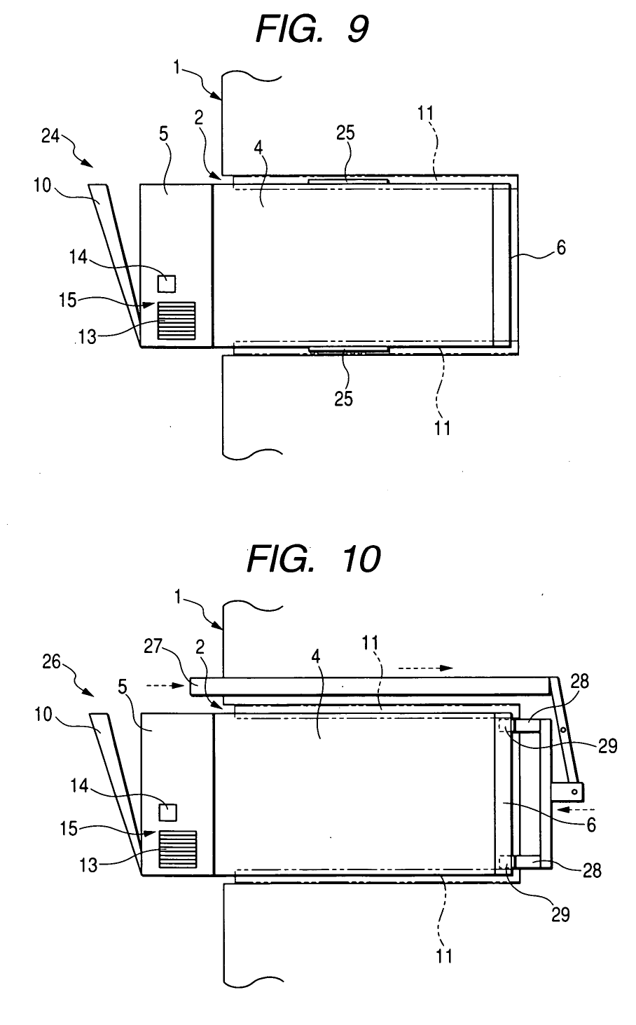

FIG. 9 is a schematic plan view showing a situation that a PC card as still another radio communication device according to the present invention is inserted into the insertion slot (card slot in the present embodiment) of the information processing terminal.

Similarly to the PC card 3, a PC card 24 as still another radio communication device is configured with the insertion portion 4 and the projection portion 5. Also, the PC card 24 comprises the interface 6, the CPU 7, the modem portion 8, the memory portion 9, the antenna portion 10, and the informing section 15. Also, pressure sensors (detector) 25 are provided to both side portions of the insertion portion 4. The pressure sensors 25 are provided to both side portions of the insertion portion 4, positioned slightly outward from a center portion, so as to project. The pressure sensors 25 are configured such that they are slightly pushed (pressed) against inner wall portions of the card guide rails 11 when the PC card 24 is inserted into the card slot 2. Therefore, when the PC card 24 inserted into the card slot 2 is to be pulled out, a pressure in the pulling-out direction can be detected by the pressure sensors 25. As a result, the detection by the pressure sensors 25 is done inevitably.

FIG. 10 is a schematic plan view showing a situation that a PC card as yet still another radio communication device according to the present invention is inserted into the insertion slot (card slot in the present embodiment) of the information processing terminal.

Similarly to the PC card 3, a PC card 26 as yet still another radio communication device is configured with the insertion portion 4 and the projection portion 5. Also, the PC card 26 comprises the interface 6, the CPU 7, the modem portion 8, the memory portion 9, the antenna portion 10, and the informing section 15. Also, sensors 29 are provided to both end portions of the insertion portion 4 on the side in which the projection portion 5 is not formed, i.e., portions opposing to card push-out members 28 that are coupled to an eject button 27 of the information processing terminal 1. The sensors 29 are configured similarly to the sensors 12 of the PC card 3, and the sensors 29 are pushed in the pulling-out direction by the card push-out members 28 when the eject button 27 is pushed. In this case, the detection by the sensors 29 is executed before the eject button 27 is completely pushed in (at least in a state that the interface 6 and the connector are connected).

In this case, changed points in the above PC cards 19, 21, 24, 26 compared to the PC card 3, i.e., respective configurations of the sensors, can also be employed in the information storing device to which the flash memory is provided.

Also, memories of a USB (universal serial bus) type, a CF (compact flash) type, a SD (secure digital) type, and the like, and a radio device may be cited as examples of the information storing device and the radio communication device except for the interface PC card of the invention of the present invention.

By employing the information device such as the information storing device and the radio communication device of the present invention configured as above, when a user tries to pull out the device by mistake from the information processing terminal, a notice is provided to prevent the pull-out. Therefore, the pull-out by mistake can be prevented beforehand. Moreover, at this time, the device is brought into a state in which a safe pull-out is possible, and also the user is informed that the device is brought into such state. Therefore, the user can pull out the device in its safe state without fail.

It will be apparent to those skilled in the art that various modifications and variations can be made to the described preferred embodiments of the present invention without departing from the spirit or scope of the invention. Thus, it is intended that the present invention cover all modifications and variations of this invention consistent with the scope of the appended claims and their equivalents.

What is claimed is:

1. An information device, comprising:
an interface connectable to an information processing terminal;
a storage;
a detector provided to be pushed or touched when the information device is pulled out from the information processing terminal, said detector detects a pushed state or a touched state of the detector;
an informing section; and
a controller which controls the informing section to give a first notice in a case where it is inappropriate to pull out the information device when the detector detects the pushed state or the touched state.

2. The information device according to claim 1, wherein said controller controls to issue a command to the information processing terminal so that the information processing terminal executes a process for enabling a safe pull-out of the information device after the first notice is given, and said controller controls the informing section to give a second notice when the information processing terminal executes the process for enabling the safe pull-out based on the command.

3. The information device according to claim 1, wherein said information device comprises:
an insertion portion positioned inside the information processing terminal in a state where the interface is connected to the information processing terminal; and
a projection portion positioned outside the information processing terminal in the state where the interface is connected to the information processing terminal,
wherein said informing section is provided in the projection portion.

4. The information device according to claim 1, wherein the case where it is inappropriate to pull out the information device signifies a case where electric power is supplied to the information device.

5. The information device according to claim 1, wherein the case where it is inappropriate to pull out the information device signifies a case where the information processing terminal does not execute a process of stopping an operation of the information device.

6. The information device according to claim 1, wherein the case where it is inappropriate to pull out the information device signifies a case where information is being written in the storage.

7. The information device according to claim 3, wherein the detector has a sensor for detecting a press or a touch thereof, and is provided in the projection portion.

8. The information device according to claim 3, wherein the detector has a sensor for detecting a press or a touch thereof, and a pair of the detectors are provided in an upper and lower portions or both side portions of the projection portion, and
when said pair of detectors are pushed or touched, the informing section gives the first notice by the control of the controller.

9. The information device according to claim 3, wherein the detector has a pressure sensor, a pair of the detectors are provided in both side portions of the insertion portion, and the pair of detectors come into contact with an inner surface of the information processing terminal in a state where the insertion portion is inserted in the information processing terminal.

10. The information device according to claim 3, wherein the detector is provided in a position that opposes to a push-out member in the information processing terminal, said push-out member being provided so as to move in a pulling-out direction when an eject button provided to the information processing terminal is pushed.

11. The information device according to claim 1, wherein the informing section includes an audio section and a display.

12. The information device according to claim 1, wherein the first notice is displayed on a display of the information processing terminal.

13. The information device according to claim 6, comprising:
a radio communicating section,
wherein the information is obtained through the radio communicating section.

14. The information device according to claim 13, wherein said controller controls to issue a command to the information processing terminal so that the information processing terminal executes a process for enabling a safe pull-out of the information device after the first notice is given, and said controller controls the informing section to give a second notice when the information processing terminal executes the process for enabling the safe pull-out based on the command.

15. The information device according to claim 13, wherein the information is PRL (roaming area information).

16. The information device according to claim 13, wherein the information is ID information.

17. The information device according to claim 13, wherein the case where it is inappropriate to pull out the information device signifies a case where a firmware or a function of the radio communicating section is updated.

18. The information device according to claim 13, wherein the case where it is inappropriate to pull out the information device signifies a case where the radio communicating section is in an idle state.

19. The information device according to claim 13, wherein the case where it is inappropriate to pull out the information device signifies a case where the radio communicating section performs a handover (handoff).
